(19) United States
(12) Patent Application Publication
(10) Pub. No.: US 2022/0299866 A1
(43) Pub. Date: Sep. 22, 2022

(54) METHODS AND MEDIA FOR RECORDING HOLOGRAMS

(71) Applicant: GOOGLE LLC, Mountain View, CA (US)

(72) Inventors: Robin W. Tsen, Kitchener (CA); Yuandong Ma, Kitchener (CA)

(21) Appl. No.: 17/638,911

(22) PCT Filed: Sep. 10, 2020
(86) PCT No.: PCT/CA2020/051219

§ 371 Date: Feb. 28, 2022

Related U.S. Application Data
(60) Provisional application No. 62/898,158, filed on Sep. 10, 2019.

(51) Int. Cl. G03F 7/00; G03F 7/095; G03H 1/18

(52) U.S. Cl. CPC G03F 7/001; G03F 7/095; G03H 1/18

(57) ABSTRACT

A method of recording multiple holograms into a holographic recording medium includes exposing the medium to a first light to cause changes in a first refractive index of at least a portion of a first layer of the medium to write a first hologram in the first layer without changing a second refractive index of a second layer of the recording medium. The method also includes exposing the medium to a second light to cause changes in a second refractive index of at least a portion of the second layer to write a second hologram in the second layer. The first layer may include a first photo-polymerizable composition polymerizable by the first light, and the second layer may include a second photo-polymerizable composition polymerizable by the second light and not polymerizable by the first light.

### BACKGROUND

Optical systems may use optical elements to manipulate light. Such optical elements may reflect, refract, or otherwise change the light. Holograms are an example of such optical elements. Holograms may be made by creating patterns of variations in the refractive index of an optical medium. Fabricating holograms by creating the variations in the refractive index may also be described as writing or recording the hologram in the medium.

### SUMMARY OF EMBODIMENTS

In one aspect, a method is provided for recording multiple holograms into a holographic recording medium, the holographic recording medium comprising a first layer of a first photo-polymerizable composition carried by a second layer of a second photo-polymerizable composition to form a stack, the method comprising: exposing the holographic recording medium to a first light having a first wavelength range to polymerize at least a portion of the first photo-polymerizable composition to cause changes in a first refractive index of at least a portion of the first layer to write a first hologram in the first layer without changing a second refractive index of the second layer, the first photo-polymerizable composition being polymerizable by the first light; and exposing the holographic recording medium to a second light having a second wavelength range to polymerize at least a portion of the second photo-polymerizable composition to cause changes in a second refractive index of at least a portion of the second layer to write a second hologram in the second layer, the second photo-polymerizable composition polymerizable by the second light and not polymerizable by the first light. The second wavelength range may comprise at least a wavelength shorter than corresponding wavelengths of the first wavelength range.

The method may further comprise: after the exposing the holographic recording medium to the first light and before the exposing the holographic recording medium to the second light, bleaching the first layer to prevent further changes to the first refractive index caused by the second light. The bleaching of the first layer may comprise exposing the holographic recording medium to a bleaching light having the first wavelength range.

The exposing the holographic recording medium to the first light may comprise exposing the first layer and the second layer to the first light; and the exposing the holographic recording medium to the second light may comprise exposing the first layer and the second layer to the second light.

The first wavelength range may correspond to red; and the second wavelength range may correspond to green and blue.

The holographic recording medium may further comprise a third layer of a third photo-polymerizable composition, the first layer, the second layer, and the third layer forming the stack; and the method may further comprise: exposing the holographic recording medium to a third light having a third wavelength range to polymerize at least a portion of the third photo-polymerizable composition to cause changes in a third refractive index in at least a portion of the third layer of the holographic recording medium to write a third hologram in the third layer, the third refractive index of the third layer being insensitive to the first light and the second light.

The first photo-polymerizable composition, the second photo-polymerizable composition, and the third photo-polymerizable composition may comprise a first photopolymer, a second photopolymer, and a third photopolymer respectively.

The first photo-polymerizable composition, the second photo-polymerizable composition, and the third photo-polymerizable composition may further comprise a first photo initiator dye, a second photo initiator dye, and a third photo initiator dye respectively.

The first wavelength range may correspond to red; the second wavelength range may correspond to green; and the third wavelength range may correspond to blue. to the first light, the second light, and the third light, bleaching the holographic recording medium to prevent further changes to the first refractive index, the second refractive index, and the third refractive index caused by the first light, the second light, and the third light.

The bleaching the holographic recording medium may comprise exposing the holographic recording medium to a bleaching light having at least one wavelength in the ultra-violet spectrum.

According to another implementation of the present specification there is provided a medium for recording a hologram, the medium comprising: a first layer of holographic film comprising a first photo-polymerizable composition comprising a first photo initiator dye, a first refractive index of the first photo-polymerizable composition to change in response to exposure to a first light having a first wavelength range, the first light to write a first hologram in the first layer; and a second layer of holographic film carried by the first layer, the first layer and the second layer arranged in a stack, the second layer comprising a second photo-polymerizable composition comprising a second photo initiator dye, a second refractive index of the second photo-polymerizable composition to change in response to exposure to a second light having a second wavelength range, the second light to write a second hologram in the second layer, the second refractive index of the second photo-polymerizable composition insensitive to the first light.

The medium may further comprise a barrier layer disposed between the first layer and the second layer.

The first photo-polymerizable composition may comprise a first photopolymer and the second photo-polymerizable composition may comprise a second photopolymer.

The first light may be to polymerize the first photopolymer to change the first refractive index in at least a portion of the first photopolymer without changing the second refractive index of the second photopolymer and the second light may be to polymerize the second photopolymer to change the second refractive index in at least a portion of the second photopolymer.

The first photo initiator dye may be sensitive to the first light; and the second photo initiator dye may be sensitive to the second light and insensitive to the first light.

The second wavelength range may comprise at least a wavelength shorter than wavelengths of the first wavelength range.

The first wavelength range may correspond to red; and the second wavelength range may correspond to green and blue.

The medium may further comprise: a third layer secured to at least one of the first layer and the second layer, the third layer comprising a third photo-polymerizable composition comprising a third photo initiator dye, a third refractive index of the third photo-polymerizable composition to change in response to exposure to a third light having a third wavelength range, the third light to write a third hologram in the third layer, the third refractive index of the third photo-polymerizable composition insensitive to the first light and the second light.

The first wavelength range may correspond to red; the second wavelength range may correspond to green; and the third wavelength range may correspond to blue.

The third layer may be disposed between the first layer and the second layer

The first wavelength range may be between the second wavelength range and the third wavelength range.

The first wavelength range may correspond to green; the second wavelength range may correspond to blue; and the third wavelength range may correspond to red.

According to yet another implementation of the present specification there is provided a holographic optical element (HOE) comprising: a first layer comprising a first hologram defined in a first photopolymer, the first hologram to interact with a first light having a first wavelength range; a second layer secured to the first layer, the second layer comprising a second hologram defined in a second photopolymer, the second hologram to interact with a second light having a second wavelength range; and a third layer secured to the first layer and the second layer, the third layer disposed between the first layer and the second layer, the third layer comprising a third hologram defined in a third photopolymer, the third hologram to interact with a third light having a third wavelength range, the first wavelength range being between the second wavelength range and the third wavelength range.

The first wavelength range may correspond to green; the second wavelength range may correspond to blue; and the third wavelength range may correspond to red.

### BRIEF DESCRIPTION OF THE DRAWINGS

In the drawings, identical reference numbers identify similar elements or acts. The relative sizes and positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn are not necessarily intended to convey any information regarding the actual shape of the particular elements, and have been solely selected for ease of recognition in the drawings.

FIG. 1 shows a flowchart of an example method for recording multiple holograms into a holographic recording medium, in accordance with a non-limiting implementation of the present specification.

FIG. 2 shows a schematic side elevation view of an example holographic recording medium, in accordance with a non-limiting implementation of the present specification.

FIG. 3 shows a schematic side elevation view of another example holographic recording medium, in accordance with a non-limiting implementation of the present specification.

FIGS. 4A, 4B, and 4C show an example set of steps for recording holograms in the recording medium of FIG. 3, in accordance with a non-limiting implementation of the present specification.

FIGS. 5A, 5B, 5C, and 5D show an example set of steps for recording holograms in another example holographic recording medium, in accordance with anon-limiting implementation of the present specification.

FIG. 6 shows a schematic side elevation view of yet another example holographic recording medium, in accordance with a non-limiting implementation of the present specification.

FIG. 7 shows a schematic representation of an example system which may be used to form or project an image viewable by a viewer, in accordance with a non-limiting implementation of the present specification.

FIG. 8 shows a partial-cutaway perspective view of an example wearable heads-up display, in accordance with a non-limiting implementation of the present specification.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, and the like. In other instances, well-known structures associated with light sources have not been shown or described in detail to avoid unnecessarily obscuring descriptions of the implementations.

Unless the context requires otherwise, throughout the specification and claims which follow, the word “comprise” and variations thereof, such as, “comprises” and “comprising” are to be construed in an open, inclusive sense, that is as “including, but not limited to.”

As used in this specification and the appended claims, the singular forms “a,” “an,” and “the” include plural referents unless the content clearly dictates otherwise. It should also be noted that the term “or” is generally employed in its broadest sense, that is as meaning“and/or” unless the content clearly dictates otherwise.

The headings and Abstract of the Disclosure provided herein are for convenience only and do not interpret the scope or meaning of the implementations.

Throughout this specification and the appended claims, the term “carries” and variants such as “carried by” are generally used to refer to a physical coupling between two objects. The physical coupling may be direct physical coupling (i.e. with direct physical contact between the two objects) or indirect physical coupling that may be mediated by one or more additional objects. Thus, the term carries and variants such as “carried by” are meant to generally encompass all manner of direct and indirect physical coupling, including without limitation: carried on, carried within, physically coupled to, secured to, and/or supported by, with or without any number of intermediary physical objects therebetween.

In multi-color or full-color optical systems multiple holograms may be used to manipulate different colors of light. These holograms are recorded in a given volume of a holographic recording medium such that they overlap or extend into one another within a given volume of the medium. Recording a hologram in the medium may also be referred to as “writing” the hologram in the medium. Such overlapping holograms may restrict the types of materials that may be used as recording media, and may pose challenges to improving the bandwidth and efficiency of the hologram for each color. Bandwidth may refer to breadth of the range of wavelengths or angles that a given hologram may handle.

Efficiency, in turn, may indicate how much of the light incident on the hologram is reflected or otherwise output by the hologram.

Using a layered medium, with each layer containing a hologram for a given color, allows for improved bandwidth and efficiency, and may increase the range of recording media materials that may be used for each of the layers. Each layer of the layered recording medium may be synthesized, positioned on a substrate, have a hologram recorded in it, removed from the substrate, and then aligned and assembled with the other layers into a stack.

Recording the layers first and then assembling them may pose several challenges. For example, assembling the multiple layers may pose an optical alignment challenge. In addition, peeling the already-recorded layers from their substrates and assembling them together may mechanically distort or damage the holograms recorded within each layer. To reduce the likelihood of such mechanical distortions, the layers may be made thicker, which in turn increases the size and weight of the layers and the stack, and may reduce the bandwidth of each layer as well.

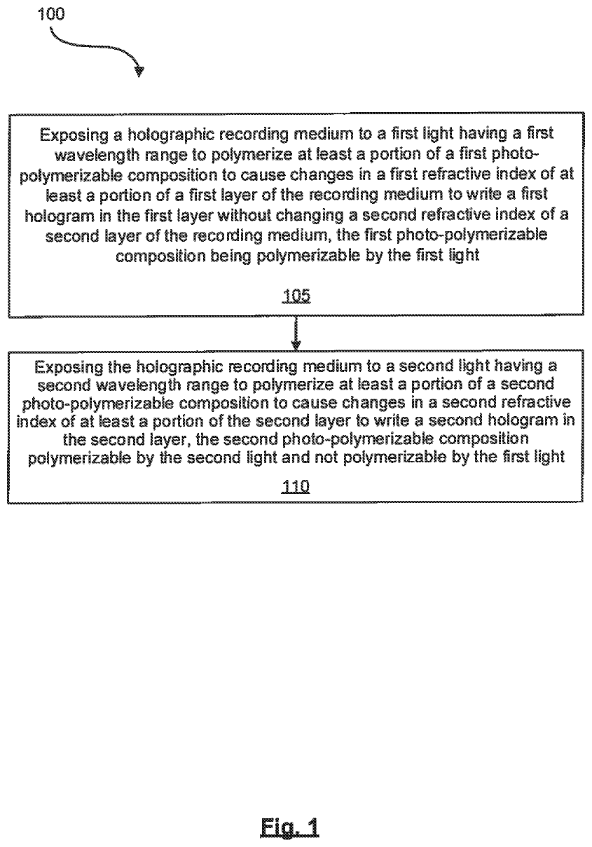

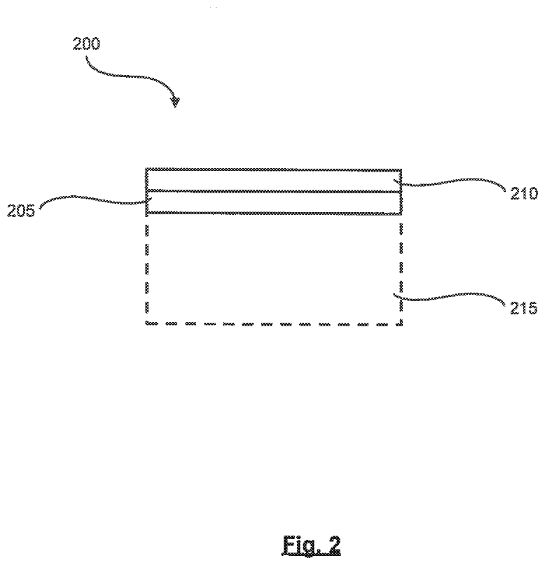

To overcome these challenges, layers of blank holographic recording media may be stacked upon one another into a single medium, and then a corresponding hologram maybe recorded in each layer. FIG. 1 shows a flowchart of an example method 100 for recording multiple holograms into a holographic recording medium. In some examples, the holographic recording medium may comprise a first layer of a first photo-polymerizable composition carried by a second layer of a second photo-polymerizable composition to form a stack. The holographic recording medium may also be referred to as the “recording medium” or the “medium” in short form. Examples of recording media are described in greater detail in relation to FIGS. 2-6.

Turning now to FIG. 1, at block 105 the holographic recording medium may be exposed to a first light having a first wavelength range. The first light may polymerize at least a portion of the first photo-polymerizable composition to cause changes in a first refractive index of those portion(s) of the first layer to write a first hologram in the first layer without changing a second refractive index of the second layer. The first photo-polymerizable composition may be polymerizable by the first light.

At block 110, the holographic recording medium is exposed to a second light having a second wavelength range. The second light may polymerize at least a portion of the second photo-polymerizable composition to cause changes in a second refractive index of those portion(s) of the second layer to write a second hologram in the second layer. The second photo-polymerizable composition may be polymerizable by the second light and not polymerizable by the first light.

In this description, the first and second photo-polymerizable compositions may respectively be referred to as the “first composition” and the “second composition” in short form. In some examples, the first and second compositions may comprise photopolymers.

In this description, depending on the context, “photopolymer” may refer to (a) a mixture of polymer precursors and a photo initiator, which mixture is capable of being at least partially photopolymerized into a resulting polymer, (b) the resulting polymer itself, or (c) a mixture of (a) and (b). In some examples, in the context of a blank holographic recording medium, “photopolymer” may refer to (a) or (c). Moreover, in some examples, in the context of a recorded holographic recording medium (also referred to as a holographic optical element), “photopolymer” may refer to (b) or (c).

In some examples the polymer precursors may comprise monomers, dimers, oligomers, and the like. Moreover, in some examples, the photo initiator may comprise a photo initiator dye, and the like. In addition, in some examples, the first and second compositions may have different polymer precursors and different photo initiators, or similar polymer precursors and different photo initiators.

In order to avoid the second refractive index of the second layer being affected by the first light, the second photo-polymerizable composition is, in one embodiment, selected to be insensitive to the first light having the first wavelength range. For example, the second photo-polymerizable composition may be selected to be sensitive to light having shorter wavelengths and higher corresponding energy than those present in the first wavelength range. As such, in some examples the second wavelength range may comprise at least a wavelength shorter than corresponding wavelengths of the first wavelength range. Such shorter wavelength(s) may be those which may cause the second composition to photopolymerize.

The first layer, whose photo-polymerizable composition is sensitive to the lower energy first wavelength range, may also be sensitive to the higher energy second wavelength range used to write the second hologram in the second layer. In order to avoid the second light impacting the first layer, in some examples the first layer can be bleached after exposing the first layer to the first light to write the first hologram in the first layer and before exposing the medium to the second light to write the second hologram in the second layer. An example of such bleaching may comprise exposing the holographic recording medium to a bleaching light. In some examples, the bleaching light may comprise an incoherent form of the first light having the first wavelength range. In some examples this incoherent light may be generated by a Light Emitting Diode (LED). Such an exposure may deactivate the photo-initiator or unpolymerized polymer precursors to render the first composition unsusceptible to further polymerization by the first light or the second light. As the second composition of the second layer is insensitive to the first light, the bleaching will not affect the second layer.

In some examples, exposing the holographic recording medium to the first light may comprise exposing the first layer and the second layer to the first light, and exposing the holographic recording medium to the second light may comprise exposing the first layer and the second layer to the second light. In this scheme, all layers of the recording medium may be exposed to the recording light during the recording of holograms in each of the layers. Since the second layer is not sensitive to the first light, being exposed to the first light need not affect the refractive index of the second layer. In addition, should any sensitivity to the first or second light remain in the first layer after writing the first hologram, a bleaching step may be used to render the first layer insensitive to refractive index changes caused by the second light.

Method 100, and the other methods described herein, may allow for recording different holograms each in a respective layer of the recording medium. This may obviate the need to record holograms in each layer first, and then assemble the layers together. This, in turn, may reduce the challenges associated with optical alignment of and thickness restrictions associated with assembling pre-recoded layers.

In addition, positioning the different holograms each in a different layer of the medium may allowed for an increased refractive index variation in each layer/hologram, which may in turn allow for increased bandwidth and efficiency of the corresponding holograms. Furthermore, the increased efficiency per hologram may allow for the use of thinner layers in the medium, which may further increase the bandwidth of the holograms. The use of thinner layers may also reduce the overall weight and volume of the recording medium.

Moreover, having one hologram per layer may reduce the variability of the bandwidth and efficiency of the hologram as a function of variability in thickness across the layer hosting or containing that hologram. In addition, recoding holograms in a medium of already-assembled layers may obviate post-recoding processing steps to optically align the various layers (and their respective holograms) with one another.

Referring back to method 100, in some examples, the first wavelength range may correspond to the color red and the second wavelength range may correspond to the colors green and blue. It is contemplated that other divisions of colors between the layers may also be used. For example, the hologram for green and blue can be divided into two separate holograms each recorded in its corresponding layer of the recording medium. To accommodate this third hologram for the third color, the recording medium may comprise a third layer of a third photo-polymerizable composition. The third layer may form a stack with the first and second layers.

In some examples, the third photo-polymerizable composition may comprise a photopolymer and a photo initiator dye. Furthermore, in some examples the photo initiator dye of the third layer can be different than the photo initiator dyes of the first and second layers. Moreover, in some examples the photopolymer precursors or the resulting photopolymer of the third layer may also be different than those of the first and second layers.

In examples where the recording medium comprises a third layer, the method of recoding holograms in the medium may also comprise exposing the holographic recording medium to a third light having a third wavelength range. The third light may polymerize at least a portion of the third photo-polymerizable composition to cause changes in a third refractive index in those portion(s) of the third layer of the holographic recording medium to write a third hologram in the third layer. The third refractive index of the third layer can be insensitive to the first light and the second light. In some examples, the first, second, and third wavelength ranges may correspond to red, green, and blue respectively. It is contemplated that in some examples colors other than red, green, and blue may also be used.

In examples where the refractive index of the second layer may be sensitive to the third light, a second bleaching operation can be performed after exposing the medium to the second light and before exposure to the third light, to render the refractive index of the second layer insensitive to the third light. In some examples, the second bleaching operation may be similar to the bleaching described in relation to the first layer, with the wavelength of the corresponding bleaching light selected to bleach the second layer.

Moreover, in some examples, after exposing the holographic recording medium to the first light, the second light, and the third light, the holographic recording medium can be bleached to prevent further changes to the first refractive index, the second refractive index, and the third refractive index caused by exposure to light. Furthermore, in some examples, such bleaching the holographic recording medium may comprise exposing the holographic recording medium to a bleaching light having at least one wavelength in the ultra-violet (UV) spectrum. In some examples this bleaching light may comprise an incoherent UV light.

Turning now to FIG. 2, a schematic side elevation view is shown of an example holographic recording medium 200. Medium 200 comprises a first layer 205 and a second layer 210. Layers 205 and 210 can be stacked upon or carried by one another. First and second layers 205 and 210 may have a composition similar to those described in relation to method 100 and the other methods described herein. Medium 200 may also comprise a substrate 215 to mechanically support layers 205 and 210. Substrate 215 is depicted in dashed lines to indicate that in some examples medium 200 need not comprise a substrate, in which examples substrate 215 may be absent. In some examples, substrate 215 may comprise, glass, polymers, ceramics, composites, and the like.

In other words, medium 200 may comprise first layer 205 of holographic film comprising a first photo-polymerizable composition comprising a first photo initiator dye. The refractive index of the first photo-polymerizable composition may change in response to exposure to a first light having a first wavelength range. The first light can be used to write a first hologram in first layer 205.

Medium 200 may also comprise second layer 210 of holographic film carried by the first layer. First layer 205 and second layer 210 may be arranged in a stack. Second layer 210 may comprise a second photo-polymerizable composition comprising a second photo initiator dye. The refractive index of the second photo-polymerizable composition may change in response to exposure to a second light having a second wavelength range. The second light can be used to write a second hologram in the second layer. In some examples, the refractive index of the second photo-polymerizable composition may be insensitive to the first light.

In addition, in some examples the first photo-polymerizable composition may comprise a first photopolymer and the second photo-polymerizable composition may comprise a second photopolymer. Moreover, in some examples, the first light may polymerize the first photopolymer to change its refractive index in at least a portion of the first photopolymer without changing the refractive index of the second photopolymer. The second light may polymerize the second photopolymer to change its refractive index in at least a portion of the second photopolymer.

In some examples the first photo initiator dye may be sensitive to the first light, and the second photo initiator dye may be sensitive to the second light and insensitive to the first light. Furthermore, in some examples, the second wavelength range may comprise at least a wavelength shorter than wavelengths of the first wavelength range. Moreover, in some examples the first wavelength range may correspond to red, and the second wavelength range may correspond to green and blue. It is contemplated that different colors or divisions of colors corresponding to the first and second layers may also be used.

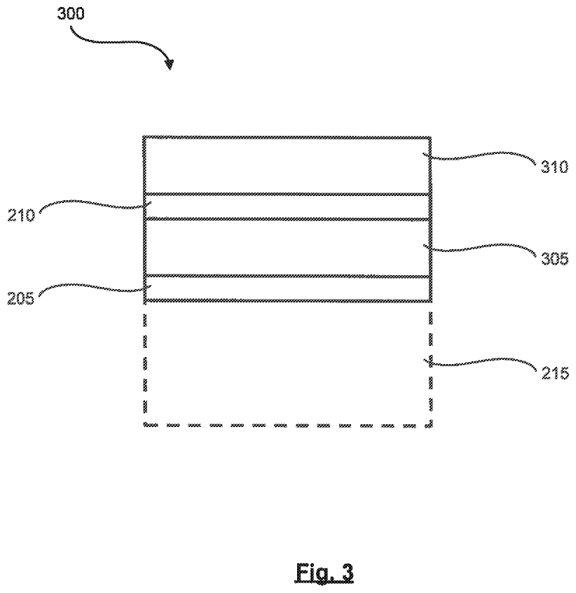

FIG. 3, in turn, shows a schematic side elevation view of an example holographic recording medium 300. Medium 300 is similar to medium 200, with a difference being that medium 300 comprises a first barrier layer 305 disposed between the first layer 205 and the second layer 210, and a second barrier layer 310 disposed on a side of the second layer 210 opposite first layer 205. In some examples, barrier layer 305 may separate the compositions of the first and second layers 205 and 210. As such, barrier layer 305 may reduce or prevent mixing of the components such as the photo initiator or polymer precursors of first layer 205 with those of second layer 210. Moreover, in some examples barrier layer 305 may enhance the mechanical strength of medium 300.

Furthermore, in some examples barrier layer 310 may protect second layer 210 and medium 300 from mechanical abrasion, oxidation, or other environmental damage. It is contemplated that in some examples medium 300 need not comprise barrier layers 305 and 310, and that one or both of barrier layers 305 and 310 may be absent. Moreover, itis contemplated that in some examples more than one layer can be interposed between the first and second layers 205 and 210, or disposed on the side of second layer 210 opposite first layer 205. In addition, in some examples, one or more layers can be interposed between first layer 205 and substrate 215. Similar to medium 200, it is contemplated that in some examples medium 300 need not comprise substrate 215, and that substrate 215 may be absent.

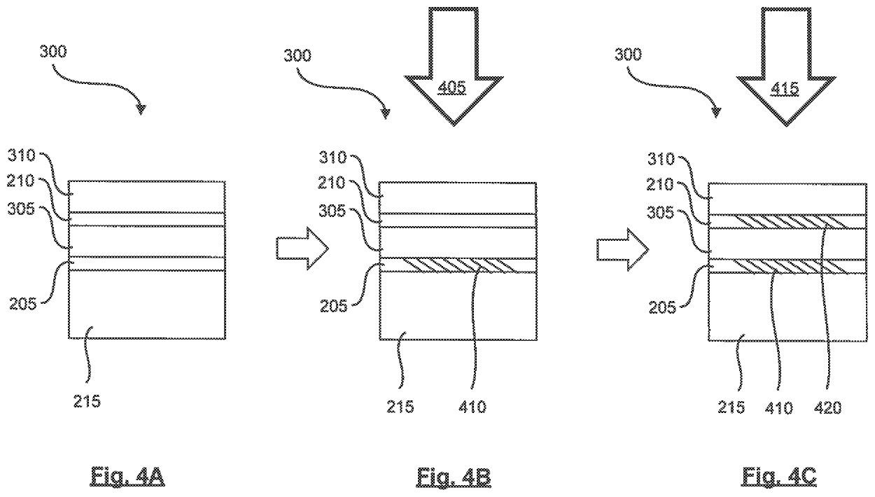

FIGS. 4A, 4B, and 4C (collectively referred to as FIG. 4) show an example set of steps for recording holograms in layers 205 and 210 of medium 300. FIG. 4A shows medium 300. In FIG. 4B, medium 300 is exposed to a first light 405 having a first wavelength range. First light 405 polymerizes at least some portions of first layer 205. This polymerization changes the refractive index in the corresponding portions of first layer 205. This pattern of refractive index modulations, in turn, is used to write or record a first hologram 410 in first layer 205. In other words, the pattern of refractive index modulations in layer 205 maybe described as forming or being hologram 410. As the composition of second layer 210 is not susceptible to being polymerized or otherwise having its refractive index altered by first light 405, no hologram is recorded by light 405 in second layer 210.

In FIG. 4B, medium 300 can be exposed to a second light 415 having a second wavelength range. Second light 415 polymerizes at least some portions of second layer 210. This polymerization changes the refractive index in the corresponding portions of second layer 210. This pattern of refractive index modulations, in turn, is used to write a second hologram 420 in second layer 210. In other words, the pattern of refractive index modulations in second layer 210 can be described as forming or being hologram 420.

In some examples, to avoid second light 415 altering or distorting first hologram 410, a bleaching step can be performed after exposing medium 300 to first light 405 to write first hologram 410 and before exposing medium 300 to second light 415 to write second hologram 420. As described above in relation to method 100 and the other methods described herein, in some examples this bleaching can be performed by exposing medium 300 to an incoherent form of light 405. Furthermore, once holograms 410 and 420 have been written in layers 205 and 210, medium 300 can be exposed to a bleaching light to prevent further unintended changes to the refractive indexes of layers 205 and 210 caused by exposure to light. In some examples, this bleaching light may comprise an incoherent UV light.

In addition, in some examples first hologram 410 may interact with red light and second hologram 420 may interact with green and blue lights. Moreover, in some examples light 405 used to write hologram 410 may comprise red light, and light 415 used to write hologram 420 may comprise green or blue lights. It is contemplated that in some examples, the relative positions of layers 205 and 210, and holograms 410 and 420, relative to one another and to medium 300, may be different than those shown in FIG. 4. In addition, in some examples the colors of light used to write holograms 410 and 420, and the colors of light that each of those holograms interact with may also be different that those described in relation to FIG. 4.

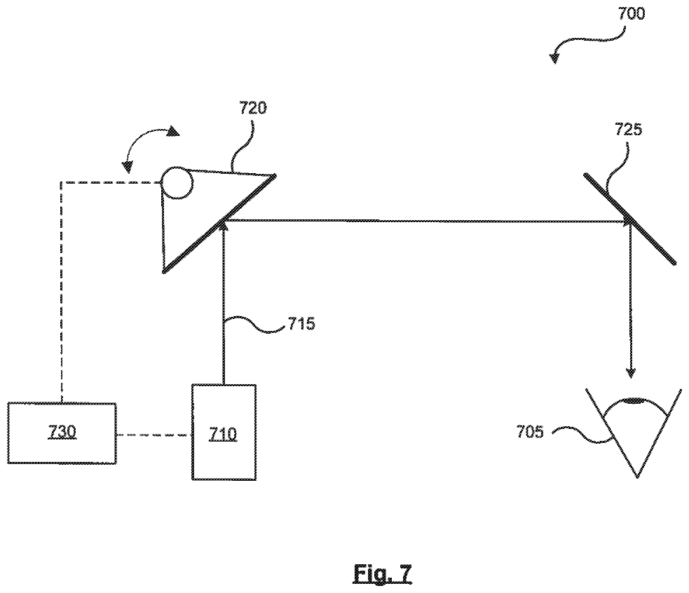

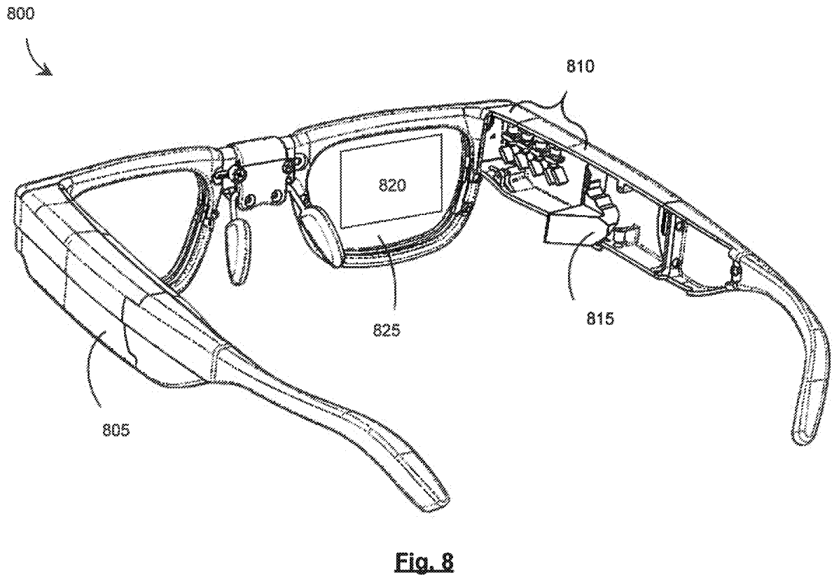

Moreover, while FIG. 4 shows the hologram in the layer closest to substrate 215 (i.e. hologram 410) being written first followed by writing of the hologram in the layer furthest from substrate 215 (i.e. hologram 420), it is contemplated that in some examples hologram 420 may be written in layer 210 followed by writing hologram 410 in layer 205. Similar steps as those shown in FIGS. 4A-C may be used to write holograms in layers 205 and 210 of medium 200 shown in FIG. 2. Once holograms have been written in the layers of media 200 or 300, these media may be used or described as holographic optical elements (HOE). In some examples, such HOEs may be used in display systems such as those described in relation to FIGS. 7 and 8.

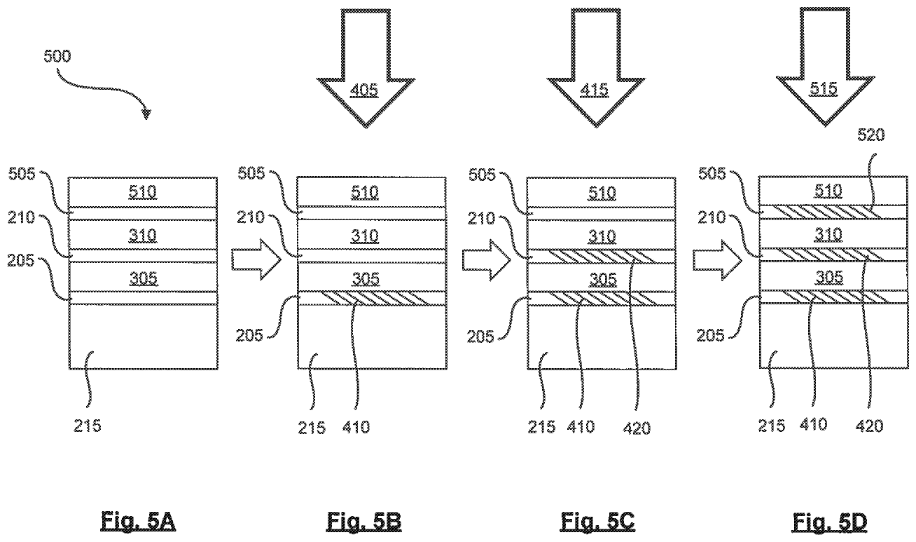

Turning now to FIGS. 5A, 5B, 5C, and 5D (collectively referred to as FIG. 5), an example set of steps are shown for recording holograms in the layers of an example medium 500. As shown in FIG. 5A, medium 500 may be similar to medium 300, with a difference being that medium 500 comprises a third layer 505, which is secured to layer 210 via barrier layer 310. It is contemplated that in some examples third layer 505 may be secured directly to one of the other two layers 205 and 210, or secured indirectly to one of the other two layers 205 and 210, for example via a barrier layer. Layer 505 may comprise a third photo-polymerizable composition comprising a third photo initiator dye. The refractive index of the third photo-polymerizable composition may change in response to exposure to a third light 515 having a third wavelength range. Third light 515 may be used to write a third hologram 520 in third layer 505. The refractive index of the third photo-polymerizable composition may be insensitive to first light 405 and second light 415.

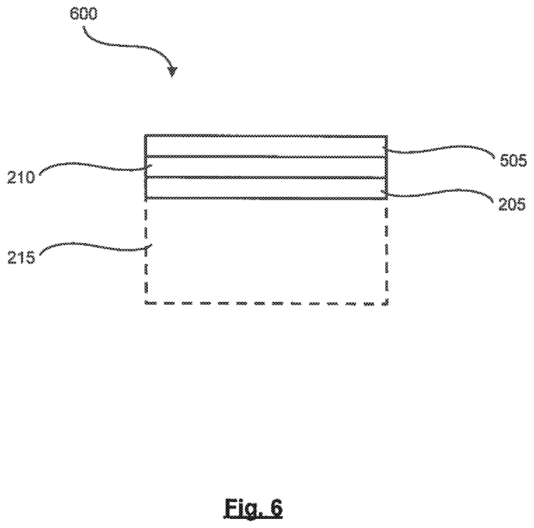

Medium 500 also comprises a barrier layer 510 disposed on a side of layer 505 opposite layers 210 and 205. Barrier layer 510 may have a composition and function similar to those of barrier layer 310. It is contemplated that in some examples, medium 500 need not comprise barrier layer 510, and that barrier layer 510 may be absent from medium 500. Furthermore, in some examples some or all of the barrier layers may be absent from medium 500. An example of such a medium with the barrier layers removed is shown in FIG. 6. Example medium 600 shown in FIG. 6 comprises three layers 205, 210, and 505 carried upon or secured to one another to form a stack. Substrate 215 is depicted in dashed lines in FIG. 6 to signify that in some examples medium 600 need not comprise a substrate and that substrate 215 may be absent from medium 600.

Moreover, it is contemplated that in some examples, one or more barrier to other types of layers may be interposed between the layers or between a layer and the substrate in the media shown in FIGS. 5 and 6. In addition, in some examples more than one layer may be disposed on the side of layer 505 opposite layers 205 and 210.

Returning to FIGS. 5A-5D, in FIG. 5B medium 500 is exposed to light 405 to write hologram 410 in layer 205. As the refractive indexes of layers 210 and 505 are insensitive to light 405, no hologram is written in layers 210 and 505 by light 405. In some examples, layer 205 may be bleached after writing hologram 410 and before exposing medium 500 to lights 415 and 515.

In FIG. 5C, medium 500 is exposed to light 415 to write hologram 420 in layer 210. As the refractive index of layer 505 is insensitive to light 415, no hologram is written in layer 505 by light 415. Moreover, either writing of hologram 410, or a combination of writing hologram 410 and subsequent bleaching, may render the refractive index of layer 205 insensitive to light 415. In some examples, layer 210 may be bleached after writing hologram 420 and before exposing medium 500 to light 515.

In FIG. 5D, medium 500 is exposed to light 515 to write hologram 520 in layer 505. Refractive indexes of layers 205 and 210 may have been rendered insensitive to light 515 as a result of writing holograms 410 and 420, or a combination of writing holograms 410 and 420 and subsequent bleaching steps. Furthermore, it is contemplated that in some examples the relative positions of layers 205, 210, and 505 to one another and to substrate 215 may be different than those shown in FIG. 5.

In some examples, the first hologram written may be the one written using the first light of the lowest energy or the corresponding wavelength range with the longest wavelengths. As the polymerization or refractive index changes of the second and third layers are sensitive only to light of energy higher than that of the first light, the refractive indexes of the second and third layers are not affected by exposure to the first light used to write the first hologram.

The second hologram written may be the one written next using the second light of middle energy relative to the first and third lights, and having the corresponding wavelength range comprising middle wavelengths. As the polymerization or refractive index changes of the third layer are sensitive only to light of energy higher than that of the first and second lights, the refractive index of the third layer is not affected by exposure to the second light used to write the second hologram. As discussed above, the first layer may also have been rendered insensitive to the second light by one or both of writing of the first hologram and a subsequent bleaching step.

The third hologram may be the one written after the first and second holograms are written. The third hologram may be written using the third light of the highest energy relative to the first and second lights, and a corresponding wavelength range having the shortest wavelengths. As discussed above, the first and second layers may have been rendered insensitive to the third light by one or both of their respective holograms and subsequent bleaching steps. As discussed above, in some examples a bleaching step may be performed after recording the third hologram to reduce or eliminate the likelihood of changes to the refractive indexes of the first, second, and third layers as a result of subsequent light exposure.

In some examples, the first, second, and third wavelength ranges of the first, second, and third lights may correspond to red, green, and blue. In such examples, the first, second, and third holograms may interact with red, green, and blue lights respectively, and be respectively referred to as the red, green, and blue holograms. In some examples there may be overlaps between the spectral ranges of the red and green holograms and the blue and green holograms. Such overlaps may cause the red and blue holograms to also reflect or otherwise interact with green light. Such reflections or interactions may cause “green ghost” artifacts when using the red, green, and blue holograms of the medium in a display system to display a color image.

To reduce green ghosts, the layer comprising the green hologram may be positioned closes to an incident light, instead of being disposed between the red and blue holograms in the optical path of the incident light. Such an arrangement may allow the green hologram to reflect some or all of the green light away from the red and blue holograms, thereby reducing the green ghost image artifacts caused by the red and blue holograms interacting with the incident green light that reaches them.

This arrangement of the middle-wavelength hologram at a position other than being physically disposed between the shortest- and longest-wavelength holograms may be applied to colors or wavelength ranges other than red, green, and blue. As discussed above, positioning the middle-wavelength hologram to be closest to the incident light, i.e. to be the first layer/hologram encountered by the incident light, may reduce ghosting artifacts caused by the shortest- or longest-wavelength holograms interacting with the incident light in the middle wavelength range.

In addition, it is contemplated that in some examples medium 500, or the other media described herein, may comprise an additional layer the refractive index of whose composition may be sensitive to light in the infra-red (IR) wavelength range to allow IR light to write a hologram in such layers. These holograms may also be designed to interact with IR light, and may be referred to as IR holograms. In such examples, the IR hologram may be written before writing the red, green, and blue holograms.

Once holograms have been written in the layers of media 500 or 600, these media may be used or described as holographic optical elements (HOEs). In some examples, such HOEs may be used in display systems such as those described in relation to FIGS. 7 and 8.

In some examples, such an HOE may comprise a first layer comprising a first hologram defined in a first photopolymer. The first hologram may interact with a first light having a first wavelength range. The HOE may also comprise a second layer secured to the first layer. The second layer may comprise a second hologram defined in a second photopolymer. The second hologram may interact with a second light having a second wavelength range. In addition, the HOE may comprise a third layer secured to the first layer and the second layer. The third layer may be disposed between the first layer and the second layer. Moreover, the third layer may comprise a third hologram defined in a third photopolymer. The third hologram, in turn, may interact with a third light having a third wavelength range. The first wavelength range may be between the second wavelength range and the third wavelength range. In some examples, the first wavelength range may correspond to green, the second wavelength range may correspond to one of blue or red, and the third wavelength range may correspond to the other one of blue or red.

While the above examples describe red, green, and glue lights being used to write red, green, and blue holograms respectively, it is contemplated that in some examples the color of light used to written a given hologram need not be similar to or otherwise linked to the color of light which that hologram reflects or otherwise interacts with. The color of the light with which a hologram interacts may be determined by the magnitude and the geometry of the patterns of refractive index modulations in the layer which hosts or contains that hologram. In examples where photopolymerization is used to create those refractive index modulations in the layers, a light of sufficient energy to initiate polymerization may be used to create the patterns of refractive index modulations and the corresponding resulting hologram. This photopolymerizing light may have a different wavelength than the wavelength of the light with which the resulting hologram interacts.

In addition, it is contemplated that in some examples the layers in the medium may each be sensitive to light of a given wavelength range which range does not overlap with the wavelength ranges where the other layers have sensitivity. In such examples, the medium may be exposed to all the recoding lights simultaneously to write the holograms in their correspondingly layers simultaneously.

Furthermore, it is contemplated that in some examples the patterns of variations in the refractive index of the layers of the medium may be generated using processes other than polymerization. For example, the patterns of variations in the refractive index of the layers may be generated using types of electromagnetic radiation other than visible or near-visible light, acoustic waves, particle streams, ionizing radiation, electrical or magnetic forces, thermal energy, mechanical forces, and the like. In such examples, the composition of the layers may be other than a photopolymerizable composition, and maybe chosen to be sensitive to the form of energy used to generate the refractive index changes.

Turning now to FIG. 7, a schematic representation of an example system 700 is shown. System 700 may be used to form or project an image viewable by an eye 705 of a viewer. System 700 may also be referred to or described as an image projection device, a display device, or a display system. System 700 may comprise a light source 710 to generate a source light 715. Light source 710 may comprise a laser, a light emitting diode, and the like. System 700 may also comprise a spatial modulator 720 to receive source light 715 from light source 710. In some examples, spatial modulator 720 may comprise a movable reflector, a micro-electro-mechanical system (MEMS), a digital micromirror device (DMD), and the like.

Furthermore, system 700 may comprise a display element 725 to receive source light 715 from spatial modulator 720 and direct the source light towards eye 705 of a viewer. In some examples, display element 725 may comprise an optical combiner such as a HOE, and the like. In some examples display element 725 may comprise HOEs described in relation to FIGS. 4C and 5D, or the other HOEs described herein. Moreover, in some examples system 700 may be a part of or incorporated into a wearable heads-up display. Such a heads-up display may have different designs or form factors, such as the form factor of eyeglasses, as is described in greater detail in relation to FIG. 8. In examples where system 700 is in the form factor of glasses, display element 725 may be on or in a lens of the glasses.

In addition, system 700 comprises a controller 730 in communication with light source 710 and spatial modulator 720. Controller 730 may control light source 710 and spatial modulator 720 to project an image. In some examples, the image to be projected may be a still image, a moving image or video, an interactive image, a graphical user interface, and the like.

In some examples, the controllers described herein such as controller 730 may comprise a processor in communication with a non-transitory processor-readable medium. The processor-readable medium may comprise instructions to cause the processors to control the light source and the spatial modulator as described in relation to the methods and systems described herein. Moreover, in some examples the controllers may be free-standing components, while in other examples the controllers may comprise functional modules incorporated into other components of their respective systems.

Furthermore, in some examples the controllers or their functionality may be implemented in other ways, including: via Application Specific Integrated Circuits (ASICs), in standard integrated circuits, as one or more computer programs executed by one or more computers (e.g., as one or more programs running on one or more computer systems), as one or more programs executed by on one or more controllers (e.g., microcontrollers), as one or more programs executed by one or more processors (e.g., microprocessors, central processing units, graphical processing units), as firmware, and the like, or as a combination thereof.

Turning now to FIG. 8, a partial-cutaway perspective view of an example wearable heads-up display (WHUD) 800 is shown. WHUD 800 includes a support structure 805 that in use is worn on the head of a user and has the general form factor and appearance of an eyeglasses (e.g., sunglasses) frame. Eyeglasses or sunglasses may also be generically referred to as “glasses”. Support structure 805 may carry components of a system to display an image, such as system 700. For example, the light source module may be received in a space 810 in a side arm of support structure 805. In other examples, one or more of the image projection and brightness adjustment system components or systems described herein may be received in or carried by support structure 805.

The spatial modulator of the systems described herein may be received in or be part of component 815 of support structure 805. The spatial modulator in turn may direct the source light onto a display element 820 carried by a lens 825 of support structure 805. In some examples, display element 820 may be similar in structure or function to display element 725. Display element 820 may comprise HOEs described in relation to FIGS. 4C and 5D, or the other HOEs described herein.

Method 100 and the other methods described herein may be used in conjunction with holographic recording media 200, 300, 500, and 600 and the other media described herein to form the HOEs described herein. It is also contemplated that method 100 and the other methods described herein may also be used in conjunction with other holographic recording media to form HOEs similar to or different than those described herein. Moreover, the holographic recording media described herein may be used in conjunction with methods of recoding holograms other than method 100 and the other methods described herein. The holographic recording media described herein may also be used to form HOEs other than those described herein. Furthermore, it is contemplated that the HOEs described herein may be formed using methods or media other than the methods and media described herein.

Throughout this specification and the appended claims, infinitive verb forms are often used. Examples include, without limitation: “to form,” “to polymerize,” “to write,” “to prevent,” and the like. Unless the specific context requires otherwise, such infinitive verb forms are used in an open, inclusive sense, that is as “to, at least, form,” to, at least, polymerize,” “to, at least, write,” and so on.

The above description of illustrated example implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. Moreover, the various example implementations described herein may be combined to provide further implementations.

In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A method of recording multiple holograms into a holographic recording medium, the holographic recording medium comprising a first layer of a first photo-polymerizable composition carried by a second layer of a second photo-polymerizable composition to form a stack, the method comprising:
exposing the holographic recording medium to a first light having a first wavelength range to polymerize at least a portion of the first photo-polymerizable composition to cause changes in a first refractive index of at least a portion of the first layer to write a first hologram in the first layer without changing a second refractive index of the second layer, the first photo-polymerizable composition being polymerizable by the first light; and
exposing the holographic recording medium to a second light having a second wavelength range to polymerize at least a portion of the second photo-polymerizable composition to cause changes in a second refractive index f at least a portion of the second layer to write a second hologram in the second layer, the second photo-polymerizable composition polymerizable by the second light and not polymerizable by the first light.

2. The method of claim 1, wherein the second wavelength range comprises at least a wavelength shorter than corresponding wavelengths of the first wavelength range.

3. The method of claim 1, further comprising:
after the exposing the holographic recording medium to the first light and before the exposing the holographic recording medium to the second light, bleaching the first layer to prevent further changes to the first refractive index caused by the second light.

4. The method of claim 3, wherein the bleaching the first layer comprises exposing the holographic recording medium to a bleaching light having the first wavelength range.

5. The method of claim 1, wherein:
exposing the holographic recording medium to the first light comprises exposing the first layer and the second layer to the first light; and
exposing the holographic recording medium to the second light comprises exposing the first layer and the second layer to the second light.

6. The method of claim 1, wherein:
the first wavelength range corresponds to red; and
the second wavelength range corresponds to green and blue.

7. The method of claim 1, wherein:
the holographic recording medium further comprises a third layer of a third photo-polymerizable composition, the first layer, the second layer, and the third layer forming the stack; and
the method further comprising:
exposing the holographic recording medium to a third light having a third wavelength range to polymerize at least a portion of the third photo-polymerizable composition to cause changes in a third refractive index in at least a portion of the third layer of the holographic recording medium to write a third hologram in the third layer, the third refractive index of the third layer being insensitive to the first light and the second light.

8. The method of claim 7, wherein the first photo-polymerizable composition, the second photo-polymerizable composition, and the third photo-polymerizable composition comprise a first photopolymer, a second photopolymer, and a third photopolymer respectively.

9. The method of claim 8, wherein the first photo-polymerizable composition, the second photo-polymerizable composition, and the third photo-polymerizable composition further comprise a first photo initiator dye, a second photo initiator dye, and a third photo initiator dye respectively.

10. (canceled)

11. The method of claim 7, further comprising:
after the exposing the holographic recording medium to the first light, the second light, and the third light, bleaching the holographic recording medium to prevent further changes to the first refractive index, the second refractive index, and the third refractive index caused by the first light, the second light, and the third light.

12. The method of claim 11, wherein the bleaching the holographic recording medium comprises exposing the holographic recording medium to a bleaching light having at least one wavelength in the ultra-violet spectrum.

13. A medium for recording a hologram, the medium comprising:
a first layer of holographic film comprising a first photo-polymerizable composition comprising a first photo initiator dye, a first refractive index of the first photo-polymerizable composition to change in response to exposure to a first light having a first wavelength range, the first light to write a first hologram in the first layer; and
a second layer of holographic film carried by the first layer, the first layer and the second layer arranged in a stack, the second layer comprising a second photo-polymerizable composition comprising a second photo initiator dye, a second refractive index of the second photo-polymerizable composition to change in response to exposure to a second light having a second wavelength range, the second light to write a second hologram in the second layer, the second refractive index of the second photo-polymerizable composition insensitive to the first light.

14. The medium of claim 13, further comprising a barrier layer disposed between the first layer and the second layer.

15. The medium of claim 13, wherein the first photo-polymerizable composition comprises a first photopolymer and the second photo-polymerizable composition comprises a second photopolymer.

16. The medium of claim 15, wherein the first light is to polymerize the first photopolymer to change the first refractive index in at least a portion of the first photopolymer without changing the second refractive index of the second photopolymer and the second light is to polymerize the second photopolymer to change the second refractive index in at least a portion of the second photopolymer.

17. The medium of claim 13, wherein:
the first photo initiator dye is sensitive to the first light; and
the second photo initiator dye is sensitive to the second light and insensitive to the first light.

18. The medium of claim 13, wherein the second wavelength range comprises at least a wavelength shorter than wavelengths of the first wavelength range.

19. (canceled)

20. The medium of claim 13, further comprising:
a third layer secured to at least one of the first layer and the second layer, the third layer comprising a third photo-polymerizable composition comprising a third photo initiator dye, a third refractive index of the third photo-polymerizable composition to change in response to exposure to a third light having a third wavelength range, the third light to write a third hologram in the third layer, the third refractive index of the third photo-polymerizable composition insensitive to the first light and the second light.

21. (canceled)

22. The medium of claim 20, wherein the third layer is disposed between the first layer and the second layer and wherein the first wavelength range is between the second wavelength range and the third wavelength range.

23. (canceled)

24. (canceled)

25. A holographic optical element (HOE) comprising:
a first layer comprising a first hologram defined in a first photopolymer, the first hologram to interact with a first light having a first wavelength range;
a second layer secured to the first layer, the second layer comprising a second hologram defined in a second photopolymer, the second hologram to interact with a second light having a second wavelength range; and
a third layer secured to the first layer and the second layer, the third layer disposed between the first layer and the second layer, the third layer comprising a third hologram defined in a third photopolymer, the third hologram to interact with a third light having a third wavelength range, the first wavelength range being between the second wavelength range and the third wavelength range.

26. (canceled)
